(19) United States
(12) Patent Application Publication
(10) Pub. No.: US 2024/0127885 A1
(43) Pub. Date: Apr. 18, 2024

(54) MEMORY DEVICE INCLUDING SEMICONDUCTOR ELEMENT

(71) Applicant: Unisantis Electronics Singapore Pte. Ltd., Singapore (SG)

(72) Inventors: Koji SAKUI, Tokyo (JP); Nozomu HARADA, Tokyo (JP)

(21) Appl. No.: 18/484,089

(22) Filed: Oct. 10, 2023

(30) Foreign Application Priority Data
Oct. 12, 2022 (WO) PCT/JP2022/038070

(51) Int. Cl. G11C 11/4096; G11C 11/408; G11C 11/4091; G11C 11/4097; H10B 12/00

(52) U.S. Cl. CPC G11C 11/4096; G11C 11/4085; G11C 11/4091; G11C 11/4097; H10B 12/20

(57) ABSTRACT

A memory device including a semiconductor element includes two stacked memory cells including a first impurity region, first and second gate conductor layers, a second impurity region, third and fourth gate conductor layers, and a third impurity region on a P layer substrate in order from below in a vertical direction and configured to perform data write, read, and erase operation with voltage applied to each gate conductor layer. The first impurity region is connected to a first bit line. One of the first and second gate conductor layers and the other are connected to a word line and a plate line, respectively. The third and fourth gate conductor layers are each connected to the word line or plate line connected to the second or first gate conductor layer, respectively. The second and third impurity regions are connected to a source line and a second bit line, respectively.

### INCORPORATION BY REFERENCE

This application claims priority to PCT/JP2022/038070, filed Oct. 12, 2022, the entire content of which is incorporated herein by reference.

### BACKGROUND OF THE INVENTION

### Field of the Invention

The present invention relates to a memory device including a semiconductor element.

### Description of the Related Art

Increase of integration density and performance of a memory element has been requested in recent development of large scale integration (LSI) technologies.

Increase in density and performance of a memory element has been advanced. Examples of such memory elements include a dynamic random access memory (DRAM; refer to H. Chung, H. Kim, H. Kim, K. Kim, S. Kim, K. W. Song, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011), for example) in which capacitors are connected by using a surrounding gate transistor (SGT; refer to Japanese Patent Laid-open No. H02-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol. 38, No. 3, pp. 573-578 (1991)) as a select transistor, a phase change memory (PCM; refer to H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No 12, December, pp. 2201-2227 (2010), for example) in which variable resistance elements are connected, a resistive random access memory (RRAM; refer to K. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007), for example), and a magneto-resistive random access memory (MRAM; refer to W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp. 1-9 (2015), for example) in which the orientation of magnetic spin is changed by current to change resistance.

There are also DRAM memory cells (refer to Japanese Patent Laid-open No. H03-171768, M. G. Ertosun, K. Lim, C. Park, J. Oh, P. Kirsch, and K. C. Saraswat: “Novel Capacitorless Single-Transistor Charge-Trap DRAM (1T CT DRAM) Utilizing Electron,” IEEE Electron Device Letter, Vol. 31, No. 5, pp. 405-407 (2010), J. Wan, L. Rojer, A. Zaslaysky, and S. Critoloveanu: “A Compact Capacitor-Less High-Speed DRAM Using Field Effect-Controlled Charge Regeneration”, Electron Device Letters, Vol. 35, No. 2, pp. 179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32 nm Node and Beyond”, IEEE IEDM (2006), and E. Yoshida and T. Tanaka: “A Design of a Capacitorless 1T-DRAM Cell Using Gate-induced Drain-Leakage (GIDL) Current for Low-power and High-speed Embedded Memory”, IEEE IEDM pp. 913-916 (2003)) constituted by one MOS transistor without capacitors. For example, among holes and electrons generated in a channel through an impact ionization phenomenon with source-drain current of a N-channel MOS transistor, some or all of the holes are held in the channel to write logical storage data “1”. Then, the holes are removed from the channel to write logical storage data “0”. In such a memory cell, “1” writing memory cells and “0” writing memory cells randomly exist for a common select word line. When on-voltage is applied to the select word line, voltage of a floating-body channel of any selected memory cell connected to the select word line largely varies due to capacitive coupling between the gate electrode and the channel. The memory cell is required to improve operation margin decrease due to variation in the floating-body channel voltage and improve data holding characteristic decrease due to removal of some of holes as signal electric charge accumulated in the channel.

There are twin-transistor MOS transistor memory elements in which one memory cell is formed in a silicon-on-insulator (SOI) layer by using two MOS transistors (refer to, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4 pp. 765-771 (2007)). In these elements, an N⁺ layer that divides the floating-body channels of the two MOS transistors and functions as a source or a drain is formed in contact with an insulating layer on a substrate side. The N⁺ layer electrically separates the floating-body channels of the two MOS transistors. Holes as signal electric charge are accumulated only in the floating-body channel of one of the MOS transistors. The other MOS transistor serves as a switch for reading the signal holes accumulated in the one MOS transistor. Since holes as signal electric charge are accumulated in the channel of one MOS transistor in this memory cell as well, the memory cell is required to improve operation margin decrease or improve data holding characteristic decrease due to removal of some of holes as signal electric charge accumulated in the channel, similarly to the above-described memory cell constituted by one MOS transistor.

As illustrated in FIGS. 4A to 4C, a dynamic flash memory cell 111 is constituted by a MOS transistor without capacitors (refer to Japanese Patent No. 7057032 and K. Sakui, N. Harada, “Dynamic Flash Memory with Dual Gate Surrounding Gate Transistor (SGT)”, Proc. IEEE IMW, pp. 72-75 (2021)). As illustrated in FIG. 4A, a floating-body semiconductor base material 102 is positioned on a SiO₂ layer 101 of a SOI substrate. An N⁺ layer 103 connected to a source line SL and an N⁺ layer 104 connected to a bit line BL are positioned at both ends of the floating-body semiconductor base material 102. A first gate insulating layer 109a is connected to the N⁺ layer 103 and covers the floating-body semiconductor base material 102, and a second gate insulating layer 109b is connected to the N⁺ layer 104 and the first gate insulating layer 109a through a slit insulating film 110 and covers the floating-body semiconductor base material 102. A first gate conductor layer 105a covers the first gate insulating layer 109a and is connected to a plate line PL, and a second gate conductor layer 105b covers the second gate insulating layer 109b and is connected to a word line WL. The slit insulating film 110 is positioned between the first gate conductor layer 105a and the second gate conductor layer 105b. Accordingly, the memory cell 111 as a dynamic flash memory (DFM) is formed. The source line SL may be connected to the N⁺ layer 104, and the bit line BL may be connected to the N⁺ layer 103.

As illustrated in FIG. 4A, for example, zero voltage is applied to the N⁺ layer 103 and positive voltage is applied to the N⁺ layer 104 so that a first N-channel MOS transistor region provided by the floating-body semiconductor base material 102 covered by the first gate conductor layer 105a is operated as a saturation region, and a second N-channel MOS transistor region provided by the floating-body semiconductor base material 102 covered by the second gate conductor layer 105b is operated as a linear region. As a result, an inversion layer 107b is formed on the entire surface of the second N-channel MOS transistor region without a pinch-off point. The inversion layer 107b formed below the second gate conductor layer 105b connected to the word line WL functions as an effective drain of the first N-channel MOS transistor region. As a result, electric field is maximum in a boundary region of the semiconductor base material between the first N-channel MOS transistor region and the second N-channel MOS transistor region, and an impact ionization phenomenon occurs in this region. As illustrated in FIG. 4B, among electrons and holes generated through the impact ionization phenomenon, the electrons are removed from the floating-body semiconductor base material 102 but some or all of these holes 106 are held in the floating-body semiconductor base material 102. In this manner, memory write operation is performed. This state is allocated as logical storage data “1”.

As illustrated in FIG. 4C, for example, positive voltage is applied to the plate line PL, zero voltage is applied to the word line WL and the bit line BL, and negative voltage is applied to the source line SL so that the holes 106 are removed from the floating-body semiconductor base material 102 to perform erase operation. This state is allocated as logical storage data “0”. At data reading, voltage applied to the first gate conductor layer 105a connected to the plate line PL is set to be higher than threshold voltage for logical storage data “1” and lower than threshold voltage for logical storage data “0”. Accordingly, such a characteristic is obtained that no current flows when voltage of the word line WL is set to be high at reading of logical storage data “0” as illustrated in FIG. 4D. With this characteristic, the operation margin is significantly expanded as compared to the above-described memory cell. In this memory cell, since channels in the first and second N-channel MOS transistor regions with gates that are the first gate conductor layer 105a connected to the plate line PL and the second gate conductor layer 105b connected to the word line WL are connected to each other through the floating-body semiconductor base material 102, voltage variation of the floating-body semiconductor base material 102 when select pulsed voltage is applied to the word line WL is largely suppressed. Accordingly, the problems of the above-described memory cell, such as operation margin decrease or data hold characteristic decrease due to removal of some of holes as signal electric charge accumulated in a channel, are largely improved. Further characteristic improvement and increase of integration density will be required for such a memory element in the future.

### SUMMARY OF THE INVENTION

Further increase of integration density of a dynamic flash memory cell is required.

To solve the above-described problem, a memory device including a semiconductor element according to a first invention includes memory cells configured to perform data write operation, data read operation, and data erase operation with voltage applied to each of a first impurity region, a first gate conductor layer, a second gate conductor layer, a second impurity region, a third gate conductor layer, a fourth gate conductor layer, and a third impurity region.

The memory cells include:
the first impurity region, a first semiconductor layer, the second impurity region, a second semiconductor layer, and the third impurity region positioned on a substrate in order from below in a vertical direction;
a first gate insulating layer surrounding the first semiconductor layer;
a second gate insulating layer surrounding the second semiconductor layer;
the first gate conductor layer surrounding a lower part of the first gate insulating layer;
the second gate conductor layer surrounding an upper part of the first gate insulating layer at a position separated from and adjacent to the first gate conductor layer;
the third gate conductor layer surrounding a lower part of the second gate insulating layer; and
the fourth gate conductor layer surrounding an upper part of the second gate insulating layer at a position separated from and adjacent to the third gate conductor layer.

The first impurity region is connected to a first bit line.

One of the first gate conductor layer and the second gate conductor layer is connected to a word line and the other is connected to a plate line.

The third gate conductor layer is connected to the word line or the plate line connected to the second gate conductor layer.

The fourth gate conductor layer is connected to the word line or the plate line connected to the first gate conductor layer.

The second impurity region is connected to a source line and the third impurity region is connected to a second bit line.

According to a second invention, in the above-described first invention, the first bit line and the second bit line are orthogonal to a direction in which the word line, the plate line, and the source line extend in a plan view.

According to a third invention, in the above-described first invention, the first bit line partially or entirely surrounds an outer circumferential part of a bottom part of the first semiconductor layer in a plan view and is connected to the first impurity region.

According to a fourth invention, in the above-described first invention, the first gate conductor layer and the fourth gate conductor layer have equal lengths in the vertical direction, and the second gate conductor layer and the third gate conductor layer have equal lengths in the vertical direction.

According to a fifth invention, in the above-described first invention, the data write operation is executed to generate pairs of electrons and holes in one or both of the first semiconductor layer and the second semiconductor layer through an impact ionization phenomenon or gate induced drain leakage current with voltage applied to each of the first impurity region, the first gate conductor layer, the second gate conductor layer, the second impurity region, the third gate conductor layer, the fourth gate conductor layer, and the third impurity region, and retain signal electric charge of the electrons or holes in the one or both of the first semiconductor layer and the second semiconductor layer, and
the data erase operation is executed to remove the signal electric charge from the one or both of the first semiconductor layer and the second semiconductor layer with voltage applied to each of the first impurity region, the first gate conductor layer, the second gate conductor layer, the second impurity region, the third gate conductor layer, the fourth gate conductor layer, and the third impurity region.

According to a sixth invention, in the above-described first invention, the first gate conductor layer and the fourth gate conductor layer are disposed in a horizontal direction,
the first gate conductor layer and the fourth gate conductor layer are connected to the word line or the plate line at each set of a plurality of the memory cells or at a memory cell array end,
the second gate conductor layer and the third gate conductor layer are disposed in the horizontal direction, and
the second gate conductor layer and the third gate conductor layer are connected to the word line or the plate line at each set of a plurality of the memory cells or at the memory cell array end.

According to a seventh invention, in the above-described first invention, the first bit line is connected to a sense amplifier circuit through a first switch circuit, and the second bit line is connected in a shared manner to the sense amplifier circuit through a second switch circuit.

According to an eighth invention, in the above-described first invention, the first gate conductor layer and the fourth gate conductor layer are connected to a plate line drive circuit through the word line or the plate line, and
the second gate conductor layer and the third gate conductor layer are connected to a word line drive circuit through the word line or the plate line.

According to a ninth invention, in the above-described first invention, the source line is connected to a source line drive circuit.

According to a tenth invention, in the above-described first invention, the word line, the plate line, and the source line are operated in or out of synchronization.

According to an eleventh invention, in the above-described first invention, at least one of the first to fourth gate conductor layers is separated in at least two gate conductor layers in the vertical direction, and among the plurality of gate conductor layers between the source line and the corresponding bit line of the memory cells, a gate conductor layer on a side closer to the source line is connected to a first select gate line, a gate conductor layer on a side closer to the bit line is connected to a second select gate line, and any gate conductor layer between the first select gate line and the second select gate line is connected to the plate line.

According to a twelfth invention, in the above-described eleventh invention, the first select gate line, the plate line, and the source line are operated in or out of synchronization.

### BRIEF DESCRIPTION OF THE DRAWINGS

FIGS. 1A, 1B and 1C are structural diagrams of a two-tier dynamic flash memory cell according to a first embodiment;

FIG. 2A is a memory cell array block diagram of the two-tier dynamic flash memory cell according to the first embodiment;

FIG. 2B is a memory cell array block diagram of the two-tier dynamic flash memory cell according to the first embodiment;

FIG. 2C is a memory cell array block diagram of the two-tier dynamic flash memory cell according to the first embodiment;

FIG. 2D is an operation waveform diagram of the two-tier dynamic flash memory cell according to the first embodiment;

FIG. 3A is a memory cell array block diagram of a two-tier dynamic flash memory cell according to a second embodiment;

FIG. 3B is a diagram of 2×2 memory array in which a plate line PL of a non-selected page is set to voltage equal to or lower than 0 volt in the two-tier dynamic flash memory cell according to the second embodiment; and

FIGS. 4A, 4B, 4C and 4D are diagrams for description of a dynamic flash memory of a conventional example.

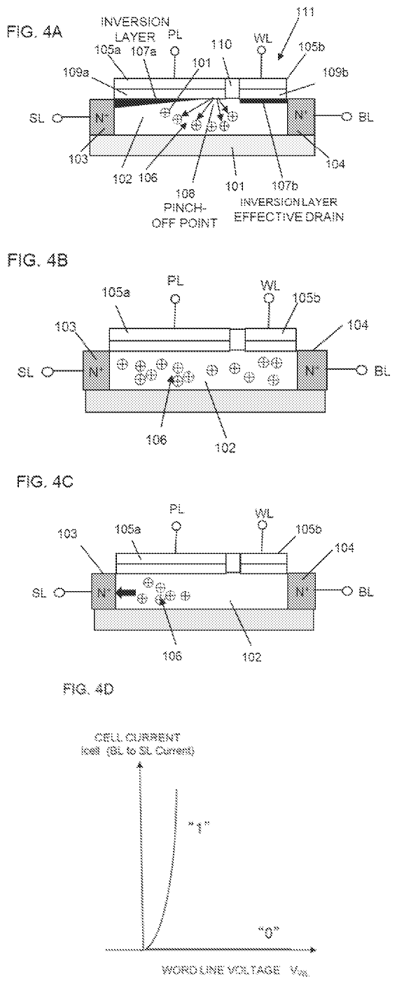

### DETAILED DESCRIPTION OF THE PREFERRED EMBODIMENTS

A memory device (hereinafter referred to as a dynamic flash memory) including a semiconductor element according to each embodiment of the present invention will be described below with reference to the accompanying drawings.

### First Embodiment

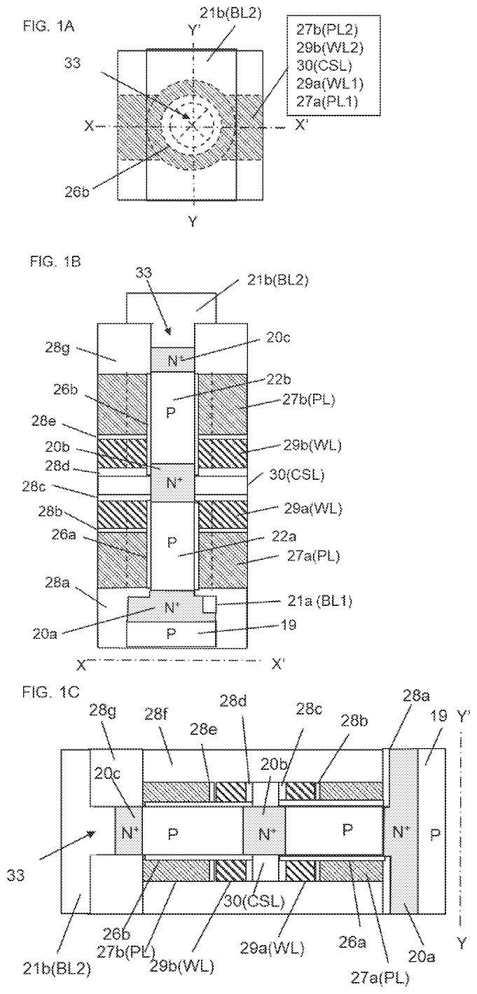

The structure of a two-tier dynamic flash memory cell according to a first embodiment of the present invention will be described below with reference to FIGS. 1A to 1C. FIG. 1A illustrates a plan view of the two-tier dynamic flash memory cell. FIG. 1B illustrates a cross-sectional view taken along line X-X′ in FIG. 1A. FIG. 1C illustrates a cross-sectional view taken along line Y-Y′ in FIG. 1A. In an actual dynamic flash memory, such two-tier dynamic flash memory cells are two-dimensionally arrayed in a large number.

An N⁺ layer 20a (example of “first impurity region” in the claims) is positioned on a P layer substrate 19 (example of “substrate” in the claims). A P layer 22a (example of “first semiconductor layer” in the claims), an N⁺ layer 20b (example of “second impurity region” in the claims), a P layer 22b (example of “second semiconductor layer” in the claims), and an N⁺ layer 20c (example of “third impurity region” in the claims) are positioned in order from below on the N⁺ layer 20a and shaped as a pillar. A wiring layer 21a (example of “first bit line” in the claims) made of metal or alloy is connected to the N⁺ layer 20a. An insulating layer 28a surrounds the P layer substrate 19, the N⁺ layer 20a, and the wiring layer 21a. A first gate insulating layer 26a (example of “first gate insulating layer” in the claims) surrounds the P layer 22a, and a second gate insulating layer 26b (example of “second gate insulating layer” in the claims) surrounds the P layer 22b. A first gate conductor layer 27a (example of “first gate conductor layer” in the claims) surrounds the lower side of the first gate insulating layer 26a. An insulating layer 28b is positioned on the first gate conductor layer 27a. A second gate conductor layer 29a (example of “second gate conductor layer” in the claims) contacts the insulating layer 28b and surrounds the upper side of the first gate insulating layer 26a. A wiring layer 30 (example of “source line” in the claims) contacts the N⁺ layer 20b and is sandwiched between insulating layers 28c and 28d in the vertical direction. A third gate conductor layer 29b (example of “third gate conductor layer” in the claims) surrounds the lower side of the second gate insulating layer 26b. A fourth gate conductor layer 27b (example of “fourth gate conductor layer” in the claims) surrounds the upper side of a second gate insulating layer 26b at a position separated from the third gate conductor layer 29b with an insulating layer 28e interposed therebetween. An insulating layer 28g covers the entire configuration. A wiring layer 21b (example of “second bit line” in the claims) is connected to the N⁺ layer 20c through a contact hole 33 opened at the insulating layer 28g on the N⁺ layer 20c. The P layers 22a and 22b desirably have equal lengths in the vertical direction. Similarly, the first gate conductor layer 27a and the fourth gate conductor layer 27b in the vertical direction desirably have equal lengths. Similarly, the second gate conductor layer 29a and the third gate conductor layer 29b desirably have equal lengths in the vertical direction.

In FIGS. 1A to 1C, a first dynamic flash memory cell is constituted by the N⁺ layer 20a, the P layer 22a, the N⁺ layer 20b, the first gate insulating layer 26a, the first gate conductor layer 27a, and the second gate conductor layer 29a. A second dynamic flash memory cell is constituted by the N⁺ layer 20b, the P layer 22b, the N⁺ layer 20c, the second gate insulating layer 26b, the third gate conductor layer 29b, and the fourth gate conductor layer 27b. The N⁺ layer 20b is shared between the first dynamic flash memory cell and the second dynamic flash memory cell.

In the first dynamic flash memory cell, the wiring layer 21a connected to the N⁺ layer 20a is connected to a first bit line BL1. The first gate conductor layer 27a is connected to a plate line PL (example of “plate line” in the claims). The second gate conductor layer 29a is connected to a word line WL (example of “word line” in the claims). The wiring layer 30 connected to the N⁺ layer 20b is connected to a source line SL. In the second dynamic flash memory cell, the wiring layer 30 connected to the N⁺ layer 20b is connected to the source line SL. The third gate conductor layer 29b is connected to the word line WL. The fourth gate conductor layer 27b is connected to the plate line PL. The wiring layer 21b connected to the N⁺ layer 20c is connected to a second bit line BL2. As described above, the wiring layer 30 connected to the N⁺ layer 20b serves as the source line SL common to the first and second dynamic flash memory cells.

In FIGS. 1A to 1C, the wiring layer 21a connected to the first bit line BL1 and the wiring layer 21b connected to the second bit line BL2 extend in the direction of line Y-Y′ in a plan view. The first gate conductor layer 27a connected to the plate line PL, the second gate conductor layer 29a connected to the word line WL, the wiring layer 30 connected to the source line SL, the third gate conductor layer 29b connected to the word line WL, and the fourth gate conductor layer 27b connected to the plate line PL extend in the direction of line X-X′ orthogonal to line Y-Y′ in a plan view. The first gate conductor layer 27a, the second gate conductor layer 29a, the wiring layer 30, the third gate conductor layer 29b, and the fourth gate conductor layer 27b formed in order from below in an overlapping manner have identical shapes in a plan view.

Accordingly, a two-tier dynamic flash memory cell in which the two dynamic flash memory cells are connected to each other in the vertical direction by sharing the N⁺ layer 20b connected to the common source line SL is formed.

The first gate conductor layer 27a and the fourth gate conductor layer 27b may be each separated in two in the vertical direction. In this case, separated gate conductor layers of the first and second dynamic flash memory cells, which are closer to the N⁺ layer 20b desirably have equal lengths in the vertical direction. Moreover, the second gate conductor layer 29a and the third gate conductor layer 29b may be each separated in at least two in the vertical direction. In this case, separated gate conductor layers of the first and second dynamic flash memory cells, which are closer to the N⁺ layer 20b desirably have equal lengths in the vertical direction. Each separated gate conductor layer may be driven out of synchronization.

Moreover, the first to fourth gate conductor layers 27a, 27b, 29a, and 29b may be each separated in at least two in a plan view. In this case, the separated first to fourth gate conductor layers 27a, 27b, 29a, and 29b are desirably formed in identical shapes in an overlapping manner in a plan view.

The first gate conductor layer 27a and the fourth gate conductor layer 27b may be connected to the word line WL, and the second gate conductor layer 29a and the third gate conductor layer 29b may be connected to the plate line PL. With this configuration as well, normal dynamic flash memory operation is performed.

The wiring layer 21a formed on the N⁺ layer 20a on one side of the P layer 22a and extending in the direction of line Y-Y′ in a plan view may be formed on the N⁺ layer 20a on each side of the P layer 22a in a plan view.

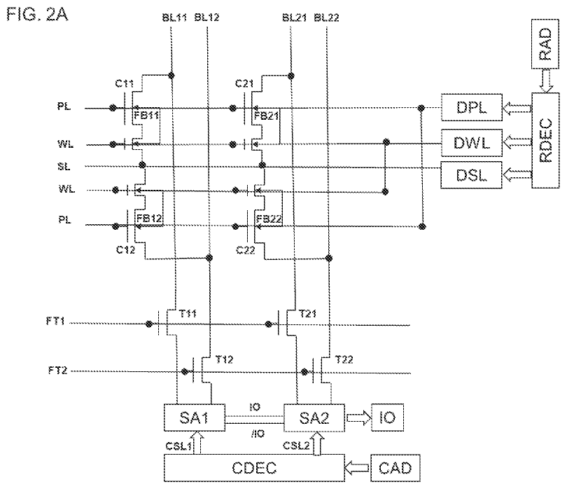

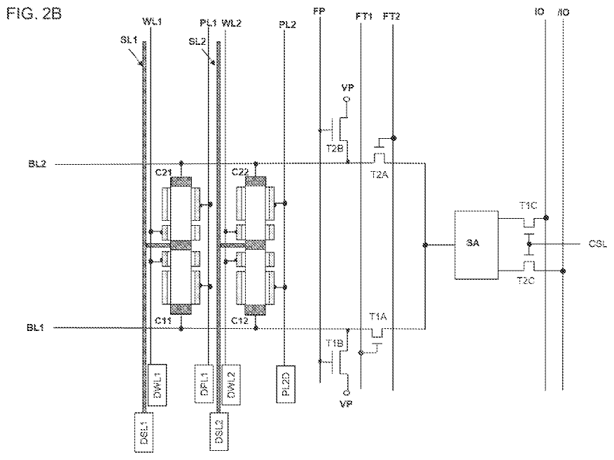

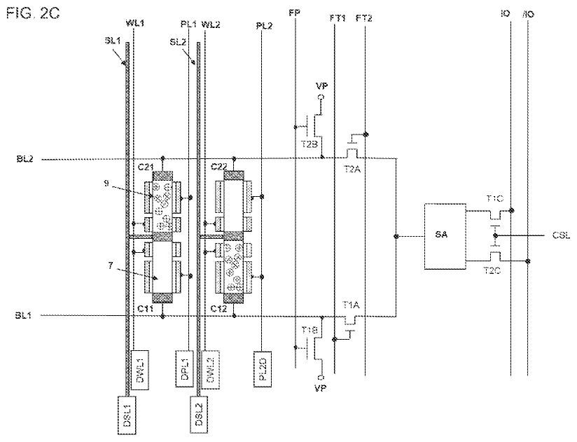

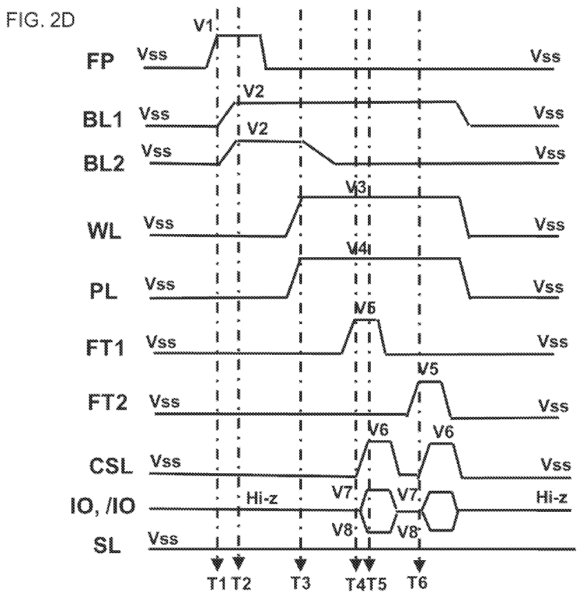

FIGS. 2A to 2D illustrate memory cell array block diagrams (FIGS. 2A to 2C) and an operation waveform diagram (FIG. 2D) in a case in which two two-tier dynamic flash memory cells according to the first embodiment of the present invention are disposed in a row direction. In the row direction of the memory cell on the lower side in the vertical direction, one of the first gate conductor layer and the second gate conductor layer is connected to the word line, and the other is connected to the plate line. In the memory cell on the upper side in the vertical direction, one of the third gate conductor layer and the fourth gate conductor layer is connected to the word line, and the other is connected to the plate line. The upper and lower bit lines in a column direction are connected to a shared sense amplifier circuit (example of “sense amplifier circuit” in the claims) through respective switch circuits. The block diagrams and operation waveform diagram of a memory array (example of “memory array” in the claims) having such a configuration will be described below.

FIG. 2A illustrates a memory cell array block diagram including main circuits. The plate line PL is constituted by the first gate conductor layer 27a of the memory cell on the lower side and the fourth gate conductor layer 27b of the memory cell on the upper side in the vertical direction in FIG. 1B, connected at each set of a plurality of memory cells in the vertical direction or at a memory cell array end, and connected to a plate line drive circuit DPL (example of “plate line drive circuit” in the claims). The word line WL is constituted by the second gate conductor layer 29a of the memory cell on the lower side and the third gate conductor layer 29b of the memory cell on the upper side in the vertical direction in FIG. 1B, connected at each set of a plurality of memory cells in the vertical direction or at the memory cell array end, and connected to a word line drive circuit DWL (example of “word line drive circuit” in the claims). The source line SL is disposed in parallel to the plate line PL and the word line WL and connected to a source line drive circuit DSL (example of “source line drive circuit” in the claims). The plate line drive circuit DPL, the word line drive circuit DWL, and the source line drive circuit DSL are connected to a row decoder circuit RDEC. A row address RAD is input to the row decoder circuit RDEC.

In FIG. 2A, bit lines BL11 and BL21 correspond to the bit line 21a (BL1) of the memory cell on the lower side in the vertical direction in FIG. 1B, and bit lines BL12 and BL22 correspond to the bit line 21b (BL2) of the memory cell on the upper side in the vertical direction in FIG. 1B. The bit line BL11 and the bit line BL12 are input to a shared sense amplifier circuit SA1 through a first switch circuit T11 (example of “first switch circuit” in the claims) and a second switch circuit T12 (example of “second switch circuit” in the claims), respectively. The bit line BL21 and the bit line BL22 are input to a shared sense amplifier circuit SA2 through a first switch circuit T21 and a second switch circuit T22, respectively. A first switch circuit drive signal FT1 is input to the gates of MOS transistors of the first switch circuits T11 and T21, and a second switch circuit drive signal FT2 is input to the gates of MOS transistors of the second switch circuits T12 and T22. The sense amplifier circuits SA1 and SA2 are connected to column selection lines CSL1 and CSL2, respectively, extending from a column decoder circuit CDEC. A column address CAD is input to a column decoder circuit CDEC.

As illustrated in FIG. 2A, the plate line PL and the word line WL extending in the row direction are shared between the memory cells on the upper and lower sides in the vertical direction in FIG. 1B and connected to the one plate line drive circuit DPL and the one word line drive circuit DWL, respectively. As a result, the number of drive circuits is halved and chip size reduction is achieved. Moreover, allowance is obtained between wires at a narrow pitch in the row direction, which is advantageous in arrangement. As for the bit lines BL in the column direction, the bit lines BL11, BL12, BL21, and BL22 on the lower and upper sides share the sense amplifier circuits SA1 and SA2 through the switch circuits T11 to T22. As a result, the number of sense amplifier circuits is halved, which leads to reduction of chip area and power necessary for sense operation.

FIG. 2B more specifically illustrates an equivalent circuit of a memory cell block in FIG. 2A. Transistors T1A and T2A to the gates of which transfer signals FT1 and FT2 are input constitute a switch circuit. The drains and sources of transistors T1B and T2B the gates of which are connected to a bit line supply signal FP are connected to a bit line supply voltage VP and the bit lines BL1 and BL2 on the upper and lower sides, respectively. The bit lines BL1 and BL2 on the upper and lower sides are connected to a sense amplifier circuit SA through the switch circuit. The sense amplifier circuit SA is connected to one pair of complementary input-output lines IO and /IO through transistors T1C and T2C the gates of which are connected to a column selection line CSL.

FIG. 2C illustrates memory cells C11 to C22 on the upper and lower sides in the vertical direction in FIG. 1B in a state in which, at an optional timing, “1” writing is randomly performed, logical “1” data is stored, and holes 9 are accumulated in a semiconductor base material 7 at the memory cells C21 and C12, and no holes 9 are accumulated in a semiconductor base material 7 and logical “0” data is stored at the memory cells C11 and C22 at which “1” writing is not performed.

Read operation at the memory cells in FIG. 2C will be described below with reference to the operation waveform diagram of FIG. 2D. At a first time point T1, the bit line supply signal FP increases from ground voltage Vss to first voltage V1. The first voltage V1 is, for example, 2.0 V and the bit line supply voltage VP is, for example, 0.6 V, and thus the N-type MOS transistors T1B and T2B operate in a linear region. As a result, at a second time point T2, the bit lines BL1 and BL2 are charged from the ground voltage Vss to second voltage V2. The ground voltage Vss is, for example, 0 volt.

At a third time point T3, the word line WL and the plate line PL are selected and increase from the ground voltage Vss to third voltage V3 and fourth voltage V4, respectively. The third voltage V3 is, for example, 1.5 V and conducts a MOS transistor region of the word line WL in a linear region. The fourth voltage V4 is, for example, 0.8 V and is the middle voltage between threshold voltages for “1” and “0” in a MOS transistor region of the plate line PL. As a result, the memory cell C21 on the upper side in which logical “1” data is stored conducts. The memory cell C11 on the lower side in which logical “0” data is stored does not conduct. Accordingly, only the bit line BL2 decreases from the second voltage V2 to the ground voltage Vss, and the bit line BL1 maintains the second voltage V2.

At a fourth time point T4, the voltage of the first switch circuit drive signal FT1 increases from the ground voltage Vss to fifth voltage V5, the bit line BL2 is connected to the shared sense amplifier circuit SA, and logical “1” data in the memory cell C21 is read to the sense amplifier circuit SA. Then, when the voltage of the column selection line CSL increases from the ground voltage Vss to sixth voltage at a fifth time point T5, the data in the sense amplifier circuit SA is read to the input-output lines IO and /IO. Subsequently at a sixth time point T6, the voltage of the second switch circuit drive signal FT2 increases from the ground voltage Vss to the fifth voltage V5, the bit line BL1 is connected to the shared sense amplifier circuit SA, and logical “0” data in the memory cell C11 is read to the sense amplifier circuit SA. In this manner, the bit lines BL1 and BL2 to be read by the shared sense amplifier circuit SA can be switched by using the first and second switch circuit drive signals FT1 and FT2.

The present embodiment has the following characteristics.
(1) As illustrated with the two-tier dynamic flash memory cells in FIGS. 2A to 2D, the present embodiment has a characteristic that the first gate conductor layer 27a and the fourth gate conductor layer 27b extending in the row direction are connected to the same plate line PL, and the second gate conductor layer 29a and the third gate conductor layer 29b are connected to the same word line WL. The plate line PL and the word line WL are connected to the one plate line drive circuit DPL and the one word line drive circuit DWL, respectively. As a result, the number of drive circuits is halved and chip size reduction is achieved. Moreover, allowance is obtained between wires at a narrow pitch in the row direction, which is advantageous in arrangement. As for the bit lines BL in the column direction, the bit lines on the lower and upper sides share the sense amplifier circuits through the switch circuits. As a result, the number of sense amplifier circuits is halved, which leads to reduction of chip area and power necessary for sense operation.
(2) In formation of the two-tier dynamic flash memory cell in FIGS. 1A to 1C, the first gate conductor layer 27a connected to a first plate line PL1, the second gate conductor layer 29a connected to a first word line WL1, the wiring layer 30 connected to a common source line CSL, the third gate conductor layer 29b connected to a second word line WL2, and the fourth gate conductor layer 27b connected to a second plate line PL2 are formed on the P layer substrate 19, the gate conductor layers having identical shapes in a plan view. This indicates that the first gate conductor layer 27a, the second gate conductor layer 29a, the wiring layer 30, the third gate conductor layer 29b, and the fourth gate conductor layer 27b can be formed by batch through single execution of a lithography process and an etching process. Accordingly, integration density increase and cost reduction of the dynamic flash memory are achieved.
(3) The N⁺ layer 20b serves as a common source line (CSL) of the two dynamic flash memory cells. Accordingly, the structure of the two-tier dynamic flash memory cell is simplified. Accordingly, integration density increase and cost reduction of the dynamic flash memory are achieved.

### Second Embodiment

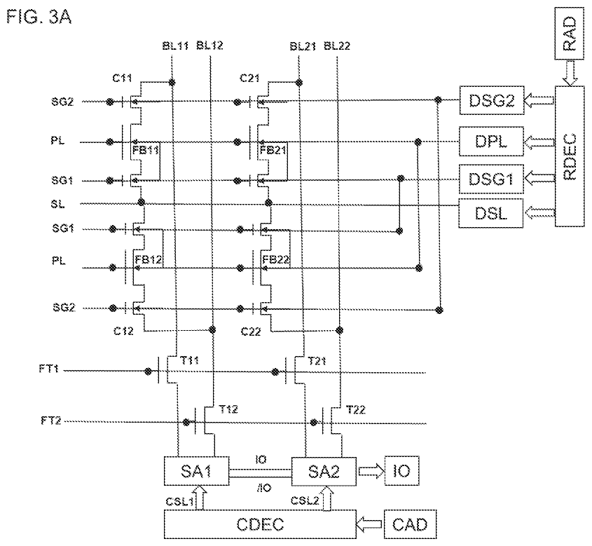

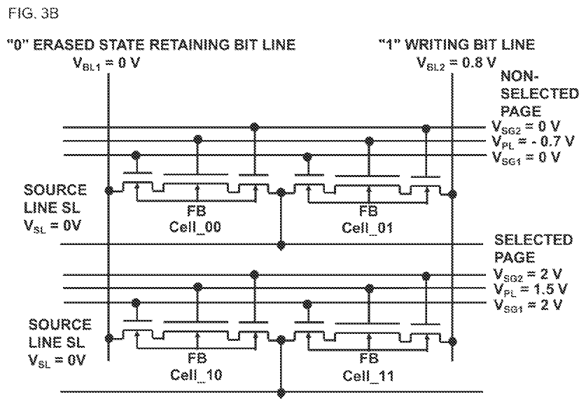

A structure in which at least one of the first to fourth gate conductor layers of a two-tier dynamic flash memory cell according to a second embodiment of the present invention is separated in at least two gate conductor layers in the vertical direction to provide at least three gate conductor layers between the source line and a bit line of the memory cell will be described below with reference to FIGS. 3A and 3B. The description is made on an example in which three gate conductor layers are provided between the source line and the bit line of the memory cell, the gate conductor layer on a side closer to the source line is connected to a first select gate line SG1 (example of “first select gate line” in the claims), the gate conductor layer on a side closer to the bit line is connected to a second select gate line SG2 (example of “second select gate line” in the claims), and the gate conductor layer therebetween is connected to the plate line PL.

FIG. 3A illustrates a memory cell array block diagram including main circuits. The plate line PL on the upper and lower sides in the vertical direction is connected at each set of a plurality of memory cells in the vertical direction or at a memory cell array end and connected to a plate line drive circuit DPL. The first select gate line SG1 is connected at each set of a plurality of memory cells in the vertical direction or at the memory cell array end and connected to a first select gate line drive circuit DSG1. The second select gate line SG2 is connected at each set of a plurality of memory cells in the vertical direction or at the memory cell array end and connected to a second select gate line drive circuit DSG2. The source line SL is disposed in parallel to the plate line PL and the word line WL and connected to the source line drive circuit DSL. The plate line drive circuit DPL, the first select gate line drive circuit DSG1, the second select gate line drive circuit DSG2, and the source line drive circuit DSL are connected to the row decoder circuit RDEC. The row address RAD is input to the row decoder circuit RDEC.

In FIG. 3A, the bit lines BL11 and BL21 show the bit line of the memory cell on the lower side in the vertical direction, and the bit lines BL12 and BL22 show the bit line of the memory cell on the upper side in the vertical direction. The bit line BL11 and the bit line BL12 are input to the shared sense amplifier circuit SA1 through the first switch circuit T11 and the second switch circuit T12, respectively. The bit line BL21 and the bit line BL22 are input to the shared sense amplifier circuit SA2 through the first switch circuit T21 and the second switch circuit T22, respectively. The first switch circuit drive signal FT1 is input to the gates of the MOS transistors of the first switch circuits T11 and T21, and the second switch circuit drive signal FT2 is input to the gates of the MOS transistors of the second switch circuits T12 and T22. The sense amplifier circuits SA1 and SA2 are connected to the column selection lines CSL1 and CSL2, respectively, extending from the column decoder circuit CDEC. The column address CAD is input to the column decoder circuit CDEC.

As illustrated in FIG. 3A, the plate line PL and the word line WL extending in the row direction are shared between the memory cells on the upper and lower sides in the vertical direction and connected to the one plate line drive circuit DPL, and the first select gate line drive circuit DSG1 and the second select gate line drive circuit DSG2, respectively. As a result, the number of drive circuits is halved and chip size reduction is achieved. Moreover, allowance is obtained between wires at a narrow pitch in the row direction, which is advantageous in arrangement. As for the bit lines BL in the column direction, the bit lines BL11, BL12, BL21, and BL22 on the lower and upper sides share the sense amplifier circuits SA1 and SA2 through the switch circuits T11 to T22. As a result, the number of sense amplifier circuits is halved, which leads to reduction of chip area and power necessary for sense operation.

Page write operation when negative voltage is applied to the plate line PL of a non-selected page will be described below with reference to FIG. 3B. In a selected page, for example, V_{BL1}=0V is applied to the bit line BL1 of a memory cell Cell_10 maintaining “0” erased data. For example, V_{BL2}=0.8 V is applied to the bit line BL2 of a memory cell Cell_11 to which “1” data is written. In addition, for example, V_{SG1}=2.0 V and V_{SG2}=2.0 V are applied to the first select gate line SG1 and the second select gate line SG2, respectively, of the selected page, and for example, V_{PL}=1.5 V is applied to the plate line PL. As a result, an impact ionization phenomenon occurs in a semiconductor base material 7a of the memory cell Cell_11, the semiconductor base material is filled with holes thus generated, and accordingly, “1” writing of the memory cell Cell_11 is performed. The voltage V_{BL}=0.8V of the bit line BL2 for “1” writing is also applied to a memory cell Cell_01 of the non-selected page since the bit line BL2 is common. In addition, for example, V_{PL}=−0.7 V is applied as the voltage of the plate line PL in the memory cell Cell_01 of the non-selected page. However, since the second select gate line SG2 of the non-selected page is positioned between the bit line BL2 and the plate line PL and voltage applied thereto is V_{SG2}=0 V, electric field between the bit line BL2 and the plate line PL of the memory cell Cell_01 is completely shielded by the second select gate line SG2. As a result, GIDL current occurs in the memory cell of the non-selected page, disturbance that storage data in the memory cell is wrongly written does not occur, and thus the memory device can achieve extremely high reliability.

The present embodiment has the following characteristics.

### Characteristic 1

The dynamic flash memory cell according to the second embodiment of the present invention has a characteristic that the plate line PL in a non-selected state is set to negative voltage lower than 0 volt. Accordingly, all plate lines PL in non-selected states are set to negative voltage of, for example, −0.7 V. As a result, holes 10 stored in the semiconductor base material 7a of each memory cell in a non-selected page can exist mainly on the plate line PL side. Accordingly, recombination of holes and electrons at the PN junction between the bit line BL and the semiconductor base material and the PN junction between the source line SL and the semiconductor base material is reduced. Moreover, no inversion layer is formed in the semiconductor base material since negative voltage is applied to the plate line PL. Accordingly, decrease of the number of holes as a signal is prevented. As a result, “1” writing retention characteristics of holes accumulated in the semiconductor base material are significantly improved.

T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol. 37, No. 11, pp1510-1522 (2002) discloses methods of extending “1” writing retention characteristics by setting a non-selected word line WL to −1.5 V. However, 1.8 V is applied to the bit line BL at writing, and thus voltage of 3.3 V is applied between the gate and the drain. It is disclosed that in this case, corruption of “0” storage data occurs with gate induced drain leakage current (GIDL current) in a memory cell connected to the non-selected WL. In the present invention, a non-selected plate line PL to which negative voltage is applied does not directly contact the bit line BL. Moreover, when 0 V is applied to the second select gate line SG2 of a non-selected page of the present invention and the bit line BL is set to, for example, 0.8 V at writing, a mere voltage of 0.8 V is applied between the gate and the drain, and thus gate induced drain leakage current does not occur.

Accordingly, negative voltage can be applied to the plate line PL of the non-selected page, and thus “1” writing retention characteristics can be significantly extended, and a highly reliable memory device can be provided.

### Characteristic 2

As for the function of the second gate conductor layer 5b connected to the plate line PL in the dynamic flash memory cell according to the second embodiment of the present invention, the voltages of the first and second select gate lines SG1 and SG2 oscillate when the dynamic flash memory cell performs write and read operation. In this case, the plate line PL functions to reduce the ratio of capacitive coupling between each of the first and second select gate lines SG1 and SG2 and the semiconductor base material 7a. As a result, it is possible to significantly reduce the influence of voltage change of the semiconductor base material 7a when the voltage of the word line WL oscillates. Accordingly, it is possible to increase the difference between SGT transistor threshold voltages of the first and second select gate lines SG1 and SG2, the difference representing logical “0” and logical “1”. This leads to expansion of the operation margin of the dynamic flash memory cell.

### OTHER EMBODIMENTS

The P layers 22a and 22b and the N⁺ layers 20a, 29b, and 20c in FIGS. 1A to 1C may be made of silicon (Si) or any other semiconductor material. This also applies to any other embodiment according to the present invention. The semiconductor material of the P layers 22a and 22b may be different from the semiconductor material of the N⁺ layers 20a, 20b, and 20c.

The first gate insulating layer 26a may be different between a region surrounded by the first gate conductor layer 27a and a region surrounded by the second gate conductor layer 29a. Similarly, the second gate insulating layer 26b may be different between a region surrounded by the third gate conductor layer 29b and a region surrounded by the fourth gate conductor layer 27b. This also applies to any other embodiment according to the present invention.

At “1” writing, pairs of electrons and holes may be generated by using gate induced drain leakage (GIDL) current disclosed in E. Yoshida and T. Tanaka: “A Design of a Capacitorless 1T-DRAM Cell Using Gate-induced Drain Leakage (GIDL) Current for Low-power and High-speed Embedded Memory”, IEEE IEDM, pp. 913-916 (2003) and a floating body FB may be filled with the generated holes. This also applies to any other embodiment according to the present invention.

The dynamic flash memory operation can be performed with a structure in which the polarity of the conduction type of each of the N⁺ layers 20a, 20b, and 20c and the P layers 22a and 22b in FIGS. 1A to 1C is inversed. In this case, the P layers 22a and 22b are N layers, and accordingly, majority carriers are electrons. Thus, electrons generated through impact ionization are signal electric charge in memory operation. This also applies to any other embodiment according to the present invention.

Although one dynamic flash memory cell is described above with reference to FIGS. 1A to 1C, the P layers 22a and 22b may be two-dimensionally arrayed in a square lattice shape, an oblique lattice shape, a zigzag shape, a sawtooth shape, or any other optional disposition to form a memory block region. This also applies to any other embodiment.

The above description with reference to FIGS. 1A to 1C is made on a configuration in which two dynamic flash memory cells are stacked on the P layer substrate 19, but three dynamic flash memory cells or four or more dynamic flash memory cells may be stacked as long as the condition that wiring layers connected to plate lines, word lines, and source lines have identical shapes in a plan view is satisfied. This also applies to any other embodiment.

For example, a silicon oxide insulator (SOI) or a well-structure substrate may be used as the P layer substrate 19 in FIGS. 1A to 1C as long as the material function as a substrate. This also applies to any other embodiment.

The shapes of the P layers 22a and 22b in a plan view are illustrated as circles in FIGS. 1A to 1C. However, the shapes of the P layers 22a and 22b in a plan view may be any other shapes such as rectangles or ellipses. This also applies to any other embodiment.

In the above description with reference to FIGS. 1A to 1C, the first gate conductor layer 27a, the second gate conductor layer 29a, the wiring layer 30, the third gate conductor layer 29b, and the fourth gate conductor layer 27b have identical shapes in a plan view, but they have difference in plan-view shape due to, for example, difference in side etching length among the layers, which occurs when etching is simultaneously performed by using one mask material layer. This also applies to any other embodiment.

In FIGS. 1A to 1C, the first gate conductor layer 27a, the second gate conductor layer 29a, the third gate conductor layer 29b, and the fourth gate conductor layer 27b may be each constituted by a plurality of layers in a horizontal section. This also applies to any other embodiment.

The present invention can have various embodiments and modifications without departing from the spirit and scope of the present invention. Each above-described embodiment is only intended to describe an example of the present invention and does not limit the scope of the present invention. Any above-described example and modification may be optionally combined. Some constituent components of the above-described embodiment may be omitted as necessary within the technological idea of the present invention.

With a memory device including a semiconductor element according to the present invention, it is possible to obtain a dynamic flash memory that is a high-density and high-performance memory device.

What is claimed is:

1. A memory device including a semiconductor element including memory cells configured to perform data write operation, data read operation, and data erase operation with voltage applied to each of a first impurity region, a first gate conductor layer, a second gate conductor layer, a second impurity region, a third gate conductor layer, a fourth gate conductor layer, and a third impurity region, the memory cells comprising:
the first impurity region, a first semiconductor layer, the second impurity region, a second semiconductor layer, and the third impurity region positioned on a substrate in order from below in a vertical direction;
a first gate insulating layer surrounding the first semiconductor layer;
a second gate insulating layer surrounding the second semiconductor layer;
the first gate conductor layer surrounding a lower part of the first gate insulating layer;
the second gate conductor layer surrounding an upper part of the first gate insulating layer at a position separated from and adjacent to the first gate conductor layer;
the third gate conductor layer surrounding a lower part of the second gate insulating layer; and
the fourth gate conductor layer surrounding an upper part of the second gate insulating layer at a position separated from and adjacent to the third gate conductor layer, wherein
the first impurity region is connected to a first bit line,
one of the first gate conductor layer and the second gate conductor layer is connected to a word line and the other is connected to a plate line,
the third gate conductor layer is connected to the word line or the plate line connected to the second gate conductor layer,
the fourth gate conductor layer is connected to the word line or the plate line connected to the first gate conductor layer, and
the second impurity region is connected to a source line and the third impurity region is connected to a second bit line.

2. The memory device including a semiconductor element according to claim 1, wherein the first bit line and the second bit line are orthogonal to a direction in which the word line, the plate line, and the source line extend in a plan view.

3. The memory device including a semiconductor element according to claim 1, wherein the first bit line partially or entirely surrounds an outer circumferential part of a bottom part of the first semiconductor layer in a plan view and is connected to the first impurity region.

4. The memory device including a semiconductor element according to claim 1, wherein
the first gate conductor layer and the fourth gate conductor layer have equal lengths in the vertical direction, and
the second gate conductor layer and the third gate conductor layer have equal lengths in the vertical direction.

5. The memory device including a semiconductor element according to claim 1, wherein
the data write operation is executed to generate pairs of electrons and holes in one or both of the first semiconductor layer and the second semiconductor layer through an impact ionization phenomenon or gate induced drain leakage current with voltage applied to each of the first impurity region, the first gate conductor layer, the second gate conductor layer, the second impurity region, the third gate conductor layer, the fourth gate conductor layer, and the third impurity region, and retain signal electric charge of the electrons or holes in the one or both of the first semiconductor layer and the second semiconductor layer, and
the data erase operation is executed to remove the signal electric charge from the one or both of the first semiconductor layer and the second semiconductor layer with voltage applied to each of the first impurity region, the first gate conductor layer, the second gate conductor layer, the second impurity region, the third gate conductor layer, the fourth gate conductor layer, and the third impurity region.

6. The memory device including a semiconductor element according to claim 1, wherein
the first gate conductor layer and the fourth gate conductor layer are disposed in a horizontal direction,
the first gate conductor layer and the fourth gate conductor layer are connected to the word line or the plate line at each set of a plurality of the memory cells or at a memory cell array end,
the second gate conductor layer and the third gate conductor layer are disposed in the horizontal direction, and
the second gate conductor layer and the third gate conductor layer are connected to the word line or the plate line at each set of a plurality of the memory cells or at the memory cell array end.

7. The memory device including a semiconductor element according to claim 1, wherein
the first bit line is connected to a sense amplifier circuit through a first switch circuit, and
the second bit line is connected in a shared manner to the sense amplifier circuit through a second switch circuit.

8. The memory device including a semiconductor element according to claim 1, wherein
the first gate conductor layer and the fourth gate conductor layer are connected to a plate line drive circuit through the word line or the plate line, and
the second gate conductor layer and the third gate conductor layer are connected to a word line drive circuit through the word line or the plate line.

9. The memory device including a semiconductor element according to claim 1, wherein the source line is connected to a source line drive circuit.

10. The memory device including a semiconductor element according to claim 1, wherein the word line, the plate line, and the source line are operated in or out of synchronization.

11. The memory device including a semiconductor element according to claim 1, wherein
at least one of the first to fourth gate conductor layers is separated in at least two gate conductor layers in the vertical direction, and
among the plurality of gate conductor layers between the source line and the corresponding bit line of the memory cells, a gate conductor layer on a side closer to the source line is connected to a first select gate line, a gate conductor layer on a side closer to the bit line is connected to a second select gate line, and any gate conductor layer between the first select gate line and the second select gate line is connected to the plate line.

12. The memory device including a semiconductor element according to claim 11, wherein the first select gate line, the plate line, and the source line are operated in or out of synchronization.
